(19) United States
(12) Patent Application Publication
(10) Pub. No.: US 2007/0053397 A1
(43) Pub. Date: Mar. 8, 2007

(54) Angled faceted emitter

(76) Inventors: David B. Burckel, Albuquerque, NM (US); Steven R. J. Brueck, Albuquerque, NM (US); Kevin J. Malloy, Albuquerque, NM (US); Andreas Stintz, Albuquerque, NM (US)

Correspondence Address: MIN, HSIEH & HACK LLP, 1951 KIDWELL DRIVE, SUITE 550, TYSONS CORNER, VA, 22182, US

(21) Appl. No.: 11/326,430

(22) Filed: Jan. 6, 2006

Related U.S. Application Data
(60) Provisional application No. 60/641,783, filed on Jan. 7, 2005.

(51) Int. Cl. H01S 5/00; H01S 3/04

(52) U.S. Cl. 372/43.01

(57) ABSTRACT

A semiconductor laser having an angled facet is provided. The semiconductor laser includes a first distributed Bragg reflector (DBR). The laser further includes an active region coupled to the first DBR, wherein the active region comprises a highly reflective facet and a partially reflective facet, and a second DBR coupled to the active region. The highly reflective facet, the partially reflective facet, the first DBR, and the second DBR form a laser cavity having a shape that is not rectangular. An angled facet emitter enables, for example, single vertical transverse mode operation of optically thick epitaxial gain regions.

### CROSS REFERENCE TO RELATED APPLICATIONS

This application claims priority from U.S. Provisional Patent Application Ser. No. 60/641,783, filed Jan. 7, 2005, which is hereby incorporated by reference in its entirety.

### GOVERNMENT INTEREST

This invention was developed under Contract F49620-03-1-0013 between the University of New Mexico and the AFOSR. The U.S. Government may have certain rights to this invention.

### FIELD OF THE INVENTION

The present invention relates to semiconductor lasers and methods for making semiconductor lasers and, more particularly, to angled facet laser cavities and methods for their manufacture.

### BACKGROUND OF THE INVENTION

Conventional semiconductor lasers can be divided into two classes: edge emitters and surface emitters. Edge emitters have a layered structure of optical materials grown by an epitaxial process on a suitable substrate in a manner such that a waveguide region is formed near the surface of the wafer containing an optical gain medium. The gain region in conventional edge emitters is typically very thin, being about one-half of the emission wavelength thick to ensure single-mode operation. The waveguide is formed into a rectangular laser cavity or resonator by cleaving the substrate and waveguide structure such that the cleaved facets are substantially normal to the waveguide axis. The optical field grows in the laser cavity and light exits through one or both of the cleaved facets, hence the term edge emitter. The vast majority of conventional edge emitters confine the light to the waveguide using total internal reflection. In this approach, the waveguide is formed with a material with a high index surrounded by a cladding of low index material. Light incident on the interface between the waveguide and the cladding at an angle exceeding the critical angle is totally internally reflected back into the waveguide.

While confinement to the waveguide in the lateral direction can be accomplished by index guided structures such as ridge waveguides or buried channel waveguides, one class of edge emitting lasers are grating confined waveguides such as the α-DFB. Grating confined waveguides employ a surface-relief distributed Bragg reflector (DBR) for lateral confinement. The nature of the Bragg reflector is such that confinement to the waveguide stripe occurs only over a narrow range of incident angles for the operation wavelength. The α-DFB is a grating confined waveguide with the waveguide stripe angled with respect to the exit facet. This places additional self-consistency constraints on the allowable field configurations in the waveguide. The result is that the laser can be made broader in the lateral direction, while still maintaining a single lateral mode profile.

Surface emitter lasers include vertical cavity surface emitting lasers (VCSELs) using distributed Bragg reflectors (DBR). In VCSELs, the laser cavity is oriented in the vertical, or growth direction, perpendicular to the surface of the wafer. The laser cavity is formed by placing an active layer, or gain medium, in an optical cavity between a pair of DBRs. The DBR is a structure composed of alternating high and low index materials with controlled thickness such that light at the laser wavelength attempting to exit the cavity is reflected back into the cavity at normal incidence. DBRs can be constructed with arbitrarily high reflectivities by adding more high/low index pairs. A conventional VCSEL is shown in FIG. 1A. A conventional VCSEL 100 includes a laser cavity formed by a first DBR 110, a second DBR 120, and an active layer 130. The direction of propagation of light is depicted by the arrows.

DBR structures have also been used to create an edge emitter laser. In this structure, the thickness of the DBR pairs are changed so that instead of reflecting laser light at normal incidence, the high reflection occurs at an angle with respect to the optical axis. The structure looks similar to the VCSEL including a rectangular laser cavity, but conducts light horizontally rather than vertically. As with other edge emitters, cleaved facets serve as end mirrors forming a resonator. This is the concept of an epitaxial transverse Bragg waveguide. As shown in FIG. 1B, an edge emitting laser 101 can include a laser cavity formed by a first DBR 111, a second DBR 121, an active layer 131, a first cleaved facet 135, and a second cleaved facet 136. The arrows represent a direction of propagation of light, such as, a guide mode.

It is desirable to create even more powerful semiconductor lasers having improved beam quality. Brightness, or peak on-axis beam power density in the far field diffraction pattern, is one measure of beam quality which is of particular interest. Increasing the output power of a semiconductor laser can be accomplished in two ways: 1) pumping the structure harder; or 2) increasing the volume of the active material. These two methods increase beam power at the expense of beam quality in all conventional types of semiconductor lasers to the point where beam quality degrades beyond acceptable levels prior to achieving the desired output brightness. Pumping a structure harder causes nonlinearities associated with non-uniform current injection, thermal lensing in the medium, filamentation, and spatial hole burning, all of which reduce beam quality and decrease brightness. Increasing the volume of the active material in the laser structure is successful up to the point where the laser cavity can support multiple transverse modes. At this point, further increases in cavity volume do not correspond to single mode emission, a requirement for achieving high power in the central lobe of the far-field diffraction pattern.

Currently, all index guided edge emitter lasers employ a cleaved facet to provide feedback into the gain region via Fresnel reflection. The devices are predominately grown on (100) surface wafers, using (110) cleavage planes for feedback. The cleaved facets may be coated so as to change their reflectivity to a higher or lower value from that of the uncoated materials. The (110) plane intersects the (100) surface at normal incidence. With facets oriented substantially normal to the waveguide axis, an edge emitter geometry laser employing index guiding for confinement to the plane containing the active medium will become multi-mode with increasing thickness as soon as the waveguide thickness is such that multiple bounce angles inside the waveguide core are supported (for thicknesses greater than about λ/2 n).

A DBR can be designed to operate at a specific wavelength over a very narrow range of incident angles by using a periodic structure with a small index contrast between the two materials making up the DBR. The result is that a waveguide formed with distributed Bragg reflectors for confinement can be made large in transverse dimensions without allowing additional higher order modes. Two problems arise, however, concerning high power operation: 1) practical concerns in the epitaxial growth of the DBR stack limits minimum realizable index contrast, and hence the minimum breadth of the angular reflectance spectrum; and 2) linear Fabry-Perot cavities formed with normally cleaved planes are subject to filamentation and spatial hole burning destroying high power, single mode operation.

Thus, there is a need to overcome these and other problems of the prior art to provide a laser cavity design which allows growth of an optically thick epitaxial gain region, effectively increasing the active volume of the structure, while maintaining single mode behavior and suppressing the onset of many of the deleterious effects associated with high pump levels.

### SUMMARY OF THE INVENTION

According to various embodiments, a semiconductor laser or angled faceted emitter is provided. The semiconductor laser can include a first distributed Bragg reflector (DBR) and a second DBR. An active layer can be disposed between the first DBR and the second DBR. The semiconductor laser can further include a highly reflective facet at an end of the active layer and a partially reflective facet at an end of the active layer opposite the highly reflective facet. The highly reflective facet, the partially reflective facet, the first DBR, and the second DBR can bound a laser cavity having a cross sectional shape that is not rectangular and the laser cavity can propagate a guided mode normal to the highly reflective facet.

According to various embodiments, a method of operating a semiconductor laser is provided. The method can include propagating light in a zig-zag path within a laser cavity comprising a gain medium, wherein the laser cavity has a cross sectional shape that is not rectangular. The gain medium can be optically pumped and light can be emitted from the laser cavity at an angle greater than 0° and less than 90° with respect to a surface of a distributed Bragg reflector forming a bottom of the laser cavity.

According to various embodiments, a method of making a semiconductor laser is provided. The method of making the semiconductor laser can include providing a substrate, forming a first distributed Bragg reflector (DBR) on the substrate, forming an active layer over the first DBR, and forming a second DBR over the active layer. The method can further include forming a first facet at a first end of the active layer and a second facet at a second end of the active layer, wherein the first facet and the second facet are disposed at an angle that is not normal relative to a surface of the first DBR.

According to various embodiments, another semiconductor laser or angled faceted emitter is provided. The semiconductor laser can include a distributed Bragg reflector (DBR) and an active layer disposed over the DBR and further comprise a highly reflective facet and a partially reflective facet. The semiconductor laser can further include a material disposed at a top surface of the active layer, wherein the highly reflective facet, the partially reflective facet, the first DBR, and the top surface of the active layer bound a laser cavity having a cross sectional shape that is not rectangular.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIG. 1A shows a cross sectional view of a conventional VCSEL.

FIG. 1B shows a cross sectional view of a conventional edge emitting laser including a pair of DBRs.

FIG. 2 depicts a cross sectional view of an angled faceted emitter including a trapezoidal shaped laser cavity in accordance with the present teachings.

FIG. 3 depicts a cross sectional view of an angled faceted emitter including a parallelogram shaped laser cavity in accordance with the present teachings.

FIG. 4 depicts a cross sectional view of an angled faceted emitter including laser cavity with top surface for total internal reflection.

FIG. 5A depicts a plan view of a device that combines an angled faceted emitter with a generalized transverse Bragg waveguide.

FIG. 5B depicts a cross sectional view of a device that combines an angled faceted emitter with a generalized transverse Bragg waveguide.

FIG. 5C depicts a top view of a device that combines an angled faceted emitter with a generalized transverse Bragg waveguide.

FIG. 6A depicts a cross sectional view of an angled faceted emitter including a trapezoidal shaped laser cavity in accordance with the present teachings.

FIG. 6B depicts a cross sectional view of an angled faceted emitter including laser cavity with top surface for total internal reflection.

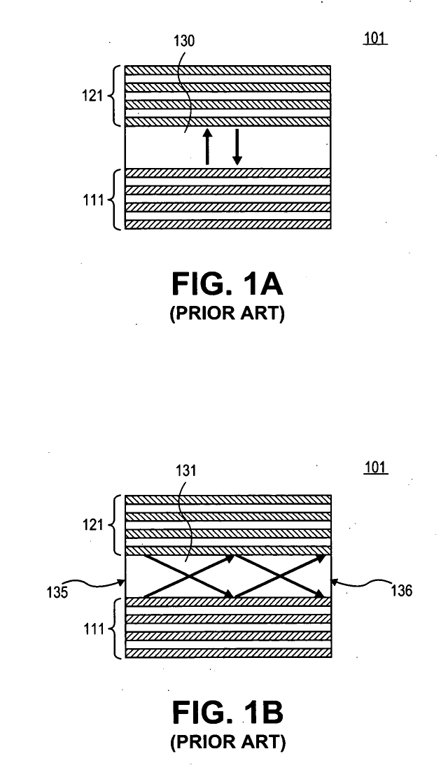

### DESCRIPTION OF THE EMBODIMENTS

In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, not to be taken in a limited sense.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

As used herein, the terms “shape” and “cross sectional shape” are used interchangeably with reference to the shape of a laser cavity and refer to a cross sectional view of the laser cavity that includes both facets of the laser cavity.

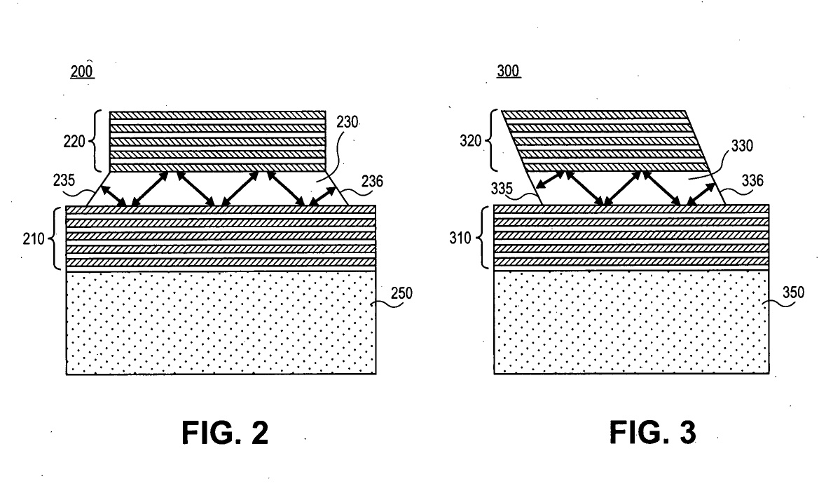

As depicted in FIGS. 2-6B, the present teachings relate to semiconductor lasers with unique laser cavity geometries. Although an angled faceted emitter is type of semiconductor laser, the term “semiconductor laser” is used interchangeably with the term “angled facet emitter” or (AFE) herein. These laser cavity geometries enable single vertical transverse mode operation of optically thick (>λ/2 n) epitaxial gain regions. Angled facets can promote lasing of an optical mode with superior high power performance over conventional typical edge emitter cavity modes.

Referring to FIG. 2, a semiconductor laser or angled faceted emitter, consistent with the present teachings is provided. A semiconductor laser 200 can include a substrate 250, a first DBR 210 disposed on substrate 250, and an active layer 230 disposed on the first DBR 210. A second DBR 220 can be disposed on active layer 230. Active layer 230 can include a highly reflective facet 235 at one end and a partially reflective facet 236 at the end opposite highly reflective facet 235. Highly reflective facet 235, partially reflective facet 236, first DBR 210, and second DBR 220 can bound the laser cavity. The device can be either electrically or optically pumped. For example, the semiconductor laser can further include electrical contacts (not shown) on the top and bottom for electrical pumping, or an appropriately transparent sub/superstrate for optical pumping. In various embodiments, highly reflective facet 235 and partially reflective facet 236 can be at an angle other than normal to a surface of first DBR 210 and/or second DBR 220. Further, according to various embodiments, by establishing a zig-zag mode profile, the high intensity portion of the optical mode is distributed substantially homogenously throughout the waveguide volume between highly reflective facet 235 and partially reflective facet 236. FIG. 2 shows, for example, highly reflective facet 235 and partially reflective facet 236 at an angle other than normal with respect to the surface of first DBR 210 such that the cross sectional shape of the laser cavity is trapezoidal. In this geometry, the laser cavity propagates a guided mode within active layer 230 that is normal to highly reflective facet 235 and/or partially reflective facet 236.

In various embodiments, first DBR 210 and/or second DBR 220 can be, for example, alternating layers of GaAs and AlGaAs. Active layer 230 can itself be formed of one or more layers of quantum wells, quantum dots, quantum wires or other gain medium known to one of ordinary skill in the art, such as but not restricted to, for example, InGaAs. In various other embodiments, semiconductor laser 200 can include a plurality of active layers 230.

In operation, first DBR 210 and/or second DBR 220 can be designed so that a wavelength is resonant with the DBRs at an angle of incidence such that the guided mode propagates normal to highly reflective facet 235 and/or partially reflective facet 236. As represented by the arrows, a zig-zag mode pattern can be established in the laser cavity. This can reduce spatial hole burning, filamentation, and thermal lensing. With sufficiently thick waveguides, the waveguide formed by the top and bottom surfaces of the laser cavity supports multiple field configurations, limited by the angular reflectivity of the DBR. However, only field configurations with nearly normal incidence to the angled facet, highly reflective facet 235 and/or partially reflective facet 236, are reflected back into self-consistent laser modes, further restricting the transverse mode profile such that a large volume single mode, and hence high brightness, laser is obtained. The result is a single transverse (vertical) mode laser with substantially thicker active region and emission normal to the angled facets 235 and 236. The beam can exit the laser cavity through partially reflective facet 236 at an angle greater than zero and less than 90 degrees with respect to a surface of first DBR 210.

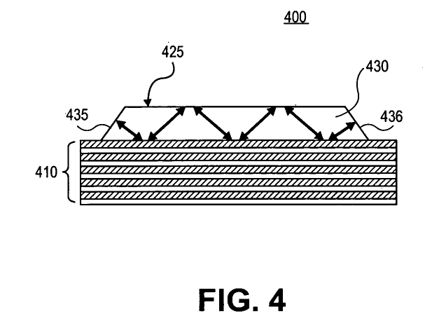

FIG. 3 shows another semiconductor laser or angled faceted emitter in accordance with the present teachings. An angled faceted emitter 300 can include a substrate 350, a first DBR 310 disposed on substrate 350, and an active layer 330 disposed on the first DBR 310. A second DBR 320 can be disposed on active layer 330. Active layer 330 can include a highly reflective facet 335 at one end and a partially reflective facet 336 at the end opposite highly reflective facet 335. In an exemplary embodiment, highly reflective facet 335 and partially reflective facet 336 can be at an angle other than normal to a surface of first DBR 310 and/or second DBR 320 such that the cross sectional shape of the laser cavity is a parallelogram. In this geometry, the laser cavity can propagate a guided mode within active layer 330 that is normal to highly reflective facet 335 and/or partially reflective facet 336. One of ordinary skill in the art will understand that the cross sectional shape of the laser cavity can be other shapes including, but not limited to, a rhombus.

As shown by the arrows, a zig-zag mode pattern can also be established in the parallelogram shaped laser cavity, so that spatial hole burning, filamentation, and thermal lensing are reduced. Aside from the larger active volume, the exit aperture of angled faceted emitter 300 is scaled by the reciprocal of the sine of the facet tilt angle, and thus is larger than the exit aperture of a similar edge emitter with normally cleaved facet. The larger aperture can provide reduced beam divergence and lower power density at the facet mitigating optical facet damage.

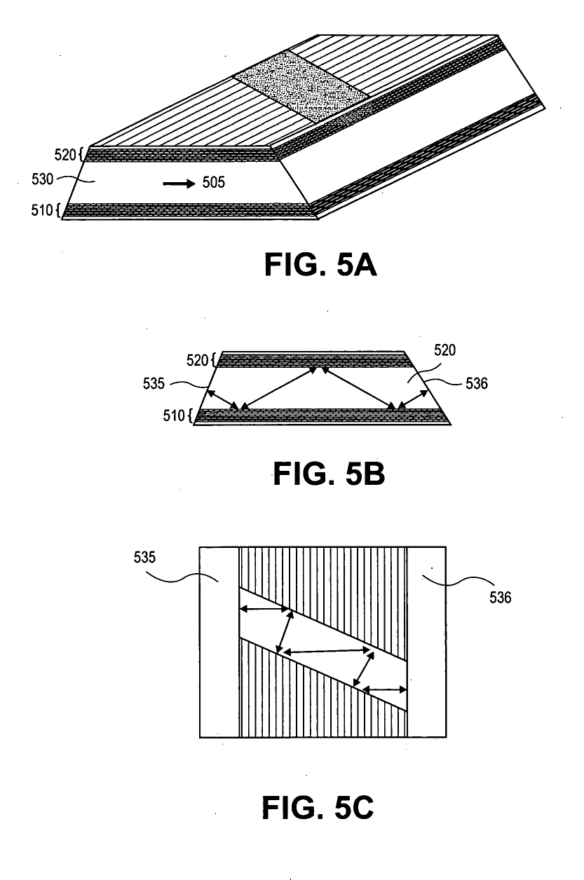

Another exemplary embodiment of a semiconductor laser or angled faceted emitter in accordance with the present teachings is shown in FIG. 4. FIG. 4 shows an angled faceted emitter 400 including a first DBR and an active layer 430 disposed on first DBR 410. Active layer 430 can further include a highly reflective facet 435 at one end and a partially reflective facet 436 at the end opposite highly reflective facet 435. In various embodiments, highly reflective facet 435 and partially reflective facet 436 can be at an angle other than normal to a surface of first DBR 410 such that the cross sectional shape of the laser cavity is not rectangular. FIG. 4 depicts an embodiment wherein the cross sectional shape of the laser cavity is a trapezoid. A top surface 425 of the laser cavity can be formed by a low index material to allow total internal reflection from this surface. Examples of low index materials include, but are not limited to, air, AlGaAs, Al₂O₃, SiO₂, SiN or other dielectric layers. In this embodiment, total internal reflection can be used for the top of the laser cavity reflection because all angles beyond about 17 degrees incidence are totally internal reflected (for the AlGaAs case). In various embodiments, a metal electrical contact can be disposed on top surface 425 and can function as a mirror.

In various embodiments, the angled faceted emitter can allow thicker epitaxial gain/waveguide regions operating in a single transverse mode. Moreover, the zig-zag path can allow high-power. In contrast with a VCSEL, the exit aperture of an angled faceted emitter can be separate from the top of the device. Thus, the entire top of the angled faceted emitter can be used to make electrical contact to the gain region.

In accordance various other embodiments, a generalized transverse Bragg waveguide can be combined with an angled faceted emitter to form a single device geometry. Generalized transverse Bragg waveguides are disclosed in U.S. patent application Ser. No. 11/231,812, filed on Sep. 22, 2005, the disclosure of which is incorporated by reference herein in its entirety. A Generalized Transverse Bragg Waveguide (GTBW) recognizes that a DBR with periodicity oriented at an angle to the waveguide axis can serve to provide lateral confinement.

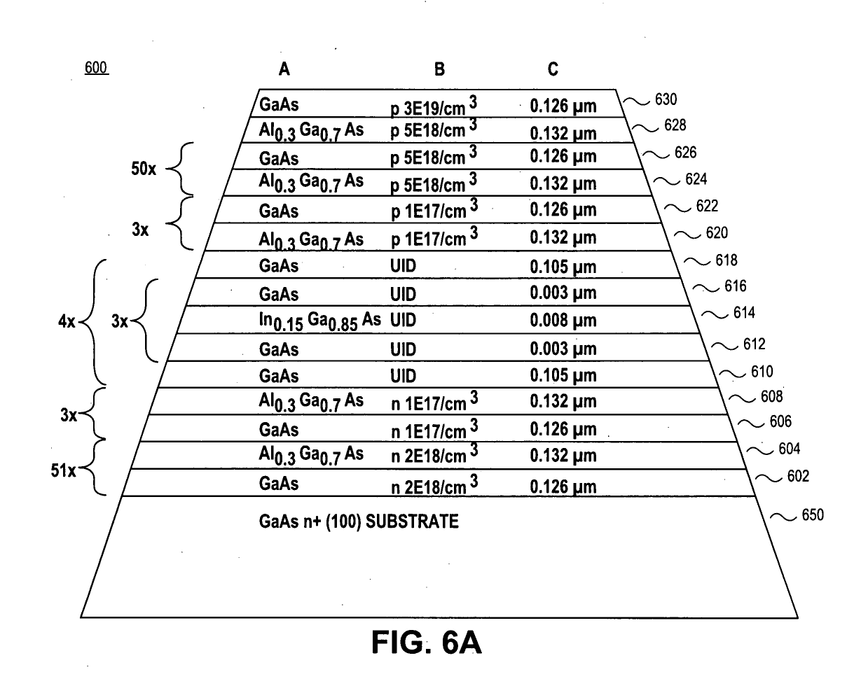

Referring to FIGS. 5A-C, a semiconductor laser 500 can include a first DBR 510, an active layer 530 disposed on the first DBR 510, and a second DBR 520 disposed on active layer 530. The periodicity of first DBR 510 and second DBR 520 can be oriented at an angle to a waveguide axis 505, as depicted by the arrow in FIG. 5A. As shown in the cross sectional view of FIG. 5B, active layer 530 can include a highly reflective facet 535 at one end and a partially reflective facet 536 at the end opposite highly reflective facet 535. Highly reflective facet 535 and partially reflective facet 536 can be at an angle other than normal to a surface of first DBR 510 and/or second DBR 520 such that the cross sectional shape of the laser cavity is, for example, a trapezoid. In this geometry, the laser cavity can propagate a guided mode that is normal to highly reflective facet 535 and/or partially reflective facet 536. FIG. 5C shows a top view of semiconductor laser 500 in which the arrows represent the zig-zag pattern of propagation in both transverse directions.

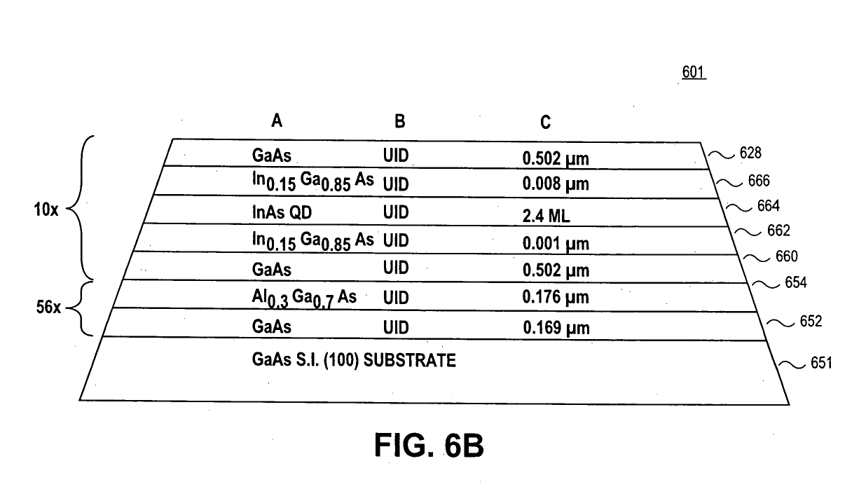

An exemplary embodiment of a semiconductor laser in accordance with the present teachings is shown in the cross sectional schematic of FIG. 6A. A layer structure of a semiconductor laser 600 can include a substantially (100) oriented n⁺ doped GaAs substrate 650. With the exception of substrate 650, the layer composition is shown in column A, the type and concentration of dopant in column B, and the layer thickness in column C. On substrate 650 can be disposed a first DBR comprising a highly n⁺-doped Bragg reflector comprising 51 pairs of 0.126 μm GaAs 602 and 0.132 μm of Al_{0.3}Ga_{0.7}As 604, and 3 pairs of lightly n⁻-doped 0.126 μm GaAs 606, and 0.132 μm of Al_{0.3}Ga_{0.7}As 608. The wavelength of the reflection maximum of this DBR can be tuned to 980 nm for a facet angle of ˜55°, which corresponds to the tilt of a [111] plane with respect to the [001] plane of substrate 650. The 54 Bragg reflector pairs 602 combined can have a reflectivity greater than 99% at 980 nm. On first DBR can be disposed a core comprising a plurality of active layers. For example the core can comprise an un-intentionally doped (UID) GaAs layer 610, a stack of 3 nm of GaAs 612, 8 nm of In_{0.15}Ga_{0.85}As 614, and 3 nm of GaAs 616 repeated three times, and a GaAs layer 618. These layers can be repeated four times to comprise the core. The In_{0.15}Ga_{0.85}As quantum wells 614 comprise the active layer, and the ground state gain of the quantum wells can be designed for a wavelength of 980 nm. At the top can be a second DBR comprising 3 pairs of a lightly p⁻-doped Bragg reflector, comprising alternating layers of Al_{0.3}Ga_{0.7}As 620 and GaAs 622, 50.5 pairs of a highly p⁺-doped Bragg reflector, comprising of alternating layers of Al_{0.3}Ga_{0.7}As 624 and 628, and GaAs 626, and a very heavily p⁺⁺-doped cap layer of GaAs 630. Semiconductor layer structure 600 can be designed to operate as a diode laser with electrical current injection.

Another exemplary embodiment of a semiconductor laser in accordance with the present teachings is shown in the cross sectional schematic of FIG. 6B. A semiconductor laser 601 can comprise a substantially (100) oriented semi-insulating GaAs substrate 651. With the exception of substrate 651, the layer composition is shown in column A, the type and concentration of dopant in column B, and the layer thickness in column C. On substrate 651 can be a first DBR comprising an un-intentionally doped Bragg reflector of 56 pairs of 0.169 μm GaAs 652 and 0.176 μm of Al_{0.3}Ga_{0.7}As 654. The wavelength of the reflection maximum of this DBR can be tuned to 1300 nm for a facet angle of ˜55°. The 56 reflector pairs 652 combined can have a reflectivity greater than 99% at 1300 nm. Above the first DBR can be core with a plurality of active layers comprising an un-intentionally doped GaAs layer 660, a 1 nm thick In_{0.15}Ga_{0.85}As quantum well 662, quantum dots equivalent to 2.4 monolayers of InAs 664, an 8 nm thick In_{0.15}Ga_{0.85}As quantum well 666, and a GaAs layer 668. These layers can be repeated ten times to form the core. The InAs quantum dots comprise the active layer, and the ground state gain of the quantum dots can be designed for a wavelength of substantially 1300 nm. The top structure of semiconductor laser 601 can be a GaAs/air interface designed for total internal reflection. This structure can be intended for operation as an optically pumped laser, with the pump light entering through the top and having an energy higher than the bandgap of GaAs for efficient absorption of the pump light.

Fabrication of exemplary angled faceted emitters can be accomplished by one or more of: 1) selective wet etch; 2) angled reactive ion etch (RIE) or chemically assisted ion beam etch (CAIBE); 3) growth on mis-oriented substrate; 4) mechanical lapping and/or polishing and 5) faceted crystal growth. Selective wet etching and faceted growth can be used to form trapezoidal shaped laser cavities cross sections, while growth on mis-oriented substrates can form a parallelogram shaped laser cavity cross sections. Ion beam etching as well as lapping and/or polishing can generate either trapezoidal or parallelogram laser cavity shapes.

For selective wet etching, advantage can be taken of the crystal plane-dependent etch rates of GaAs based semiconductors, exposing the (111) plane facet. The (111) plane makes approximately a 55 degree angle with the (100) surface. In order for light to be normally incident on the (111) plane it must reflect off the top and bottom of the cavity at this same angle. Use of a properly designed DBR can provide such a reflection for the bottom of the laser cavity.

While exemplary embodiments have been described as being disposed on a substrate, one of ordinary skill in the art will understand that the substrate is not a requirement for the devices to operate. Appropriate growth, selective etching and lift-off processes can be used to separate the device from the growth substrate for free standing operation or subsequent deposition on another substrate (e.g. wafer bonding).

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.”

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor laser comprising:
a first distributed Bragg reflector (DBR);
a second DBR;
an active layer disposed between the first DBR and the second DBR;
a highly reflective facet at an end of the active layer; and
a partially reflective facet at an end of the active layer opposite the highly reflective facet;
wherein the highly reflective facet, the partially reflective facet, the first DBR, and the second DBR bound a laser cavity having a cross sectional shape that is not rectangular, and
wherein the laser cavity propagates a guided mode normal to the highly reflective facet.

2. The semiconductor laser of claim 1, wherein the cross sectional shape of the laser cavity is a trapezoid.

3. The semiconductor laser of claim 1, wherein the cross sectional shape of the laser cavity is a parallelogram.

4. The semiconductor laser of claim 1, wherein a region of high mode intensity is distributed substantially throughout the entire volume of the waveguide.

5. The semiconductor laser of claim 1, wherein a beam exits the partially reflective facet at an angle greater than zero and less than 90 degrees with respect to a surface of the first DBR.

6. The semiconductor laser of claim 1, wherein the first DBR and the second DBR comprise alternating layers of GaAs and AlGaAs.

7. A method of operating a semiconductor laser comprising:
propagating light in a zig-zag path within a laser cavity comprising a gain medium, wherein the laser cavity has a cross sectional shape that is not rectangular;
optically pumping the gain medium; and
emitting light from the laser cavity at an angle greater than 0° and less than 90° with respect to a surface of a distributed Bragg reflector forming a bottom of the laser cavity.

8. A method of making a semiconductor laser comprising:
providing a substrate;
forming a first distributed Bragg reflector (DBR) on the substrate;
forming an active layer over the first DBR;
forming a second DBR over the active layer; and
forming a first facet at a first end of the active layer and a second facet at a second end of the active layer, wherein the first facet and the second facet are disposed at an angle that is not normal relative to a surface of the first DBR.

13. The method of claim 12 further comprising providing a highly reflective surface on the first facet and a partially reflective surface on the partially reflective facet.

14. The method of claim 12, wherein the step of forming a first facet at a first end of the active region and a second facet at a second end of the active region comprises at least one of a selective wet etch, an angled reactive ion etch, a chemically assisted ion beam etch, a growth on a mis-oriented substrate, and a faceted crystal growth.

15. The method of claim 12, further comprising forming sidewalls on the second DBR that are at an angle other than normal with respect to a surface of the first DBR.

16. The method of claim 12, further comprising forming sidewalls on the first DBR that are at an angle other than normal with respect to a surface of the second DBR.

17. A semiconductor laser comprising:
a distributed Bragg reflector (DBR);
an active layer disposed over the DBR and comprising a highly reflective facet and a partially reflective facet; and
a material disposed at a top surface of the active layer,
wherein the highly reflective facet, the partially reflective facet, the first DBR, and the top surface of the active layer bound a laser cavity having a cross sectional shape that is not rectangular.

18. The semiconductor laser of claim 17, wherein the material disposed at the top of the active layer comprises a metal.

19. The semiconductor laser of claim 17, wherein the material disposed at the top of the active layer comprises a low index material.

20. The semiconductor laser of claim 17, wherein the material disposed at the top of the active layer comprises air.
